(19) United States
(12) Patent Application Publication
(10) Pub. No.: US 2025/0100887 A1
(43) Pub. Date: Mar. 27, 2025

(54) JOULE HEATING-BASED ROLL-TO-ROLL GRAPHENE MANUFACTURING METHOD AND GRAPHENE MANUFACTURING APPARATUS

(71) Applicants: CENTER FOR ADVANCED META-MATERIALS, Daejeon (KR); KOREA INSTITUTE OF MACHINERY-MATERIALS, Daejeon (KR)

(72) Inventors: Hyun June JUNG, Daejeon (KR); Hak Joo LEE, Daejeon (KR); Jae Hyun KIM, Daejeon (KR); Kyung Sik KIM, Daejeon (KR)

(21) Appl. No.: 18/725,317

(22) PCT Filed: Dec. 13, 2022
(86) PCT No.: PCT/KR2022/020204

§ 371 Date: Dec. 10, 2024

(30) Foreign Application Priority Data
Dec. 29, 2021 (KR) 10-2021-0191732

(51) Int. Cl. C01B 32/186; C23C 16/26; C23C 16/458; C23C 16/54

(52) U.S. Cl. CPC C01B 32/186; C23C 16/26; C23C 16/458; C23C 16/545

(57) ABSTRACT

An embodiment provides a Joule heating-based roll-to-roll graphene manufacturing method and a graphene manufacturing apparatus, by suppressing the stress concentration and deformation generated in a catalytic metal passing between a first roller part and a second roller part, stable roll-to-roll transfer for a synthesis area arranged so as to extend in a downward direction can be ensured for temperature compensation, and the synthesis area is transferred in a state of maintaining a concave shape toward a temperature compensation area without a cross section distorted in the longitudinal direction.

### TECHNICAL FIELD

The present invention relates to a Joule heating-based roll-to-roll graphene manufacturing apparatus and a graphene manufacturing method, and particularly, to a Joule heating-based roll-to-roll graphene manufacturing method and graphene manufacturing apparatus for synthesizing graphene on a catalytic metal by using Joule heating, which generates heat by applying current to a conductor during a roll-to-roll process in which a catalytic metal is continuously processed while being wrapped around a roll.

### BACKGROUND ART

Materials composed of carbon atoms include fullerene, carbon nanotubes, graphene, and graphite. Among these, graphene is a structure in which carbon atoms are formed in a single layer on a two-dimensional plane.

In particular, graphene is not only very stable and excellent in electrical, mechanical, and chemical properties, but is also an excellent conductive material, moving electrons much faster than silicon and allowing much larger currents to flow than copper, wherein the facts were proven through experiments in 2004 when a method for separating graphene from graphite was discovered, and much research has been conducted to date.

The graphene may be formed on a large area, and has electrical, mechanical, and chemical stability as well as excellent conductivity, so the graphene is receiving attention as a basic material for electronic circuits.

In addition, since graphene may generally change its electrical properties depending on the crystal orientation of the graphene for a given thickness, it is easy to express the electrical properties in a direction chosen by a user, and accordingly, an element may be easily designed, and the graphene produced in this way may be effectively used in carbon-based electrical or electromagnetic elements.

A representative method for producing graphene is to use Joule heating to generate heat by applying current to electrodes in contact with a catalytic metal, thereby synthesizing graphene on the catalytic metal.

However, in the conventional method of producing graphene using Joule heating, when current is supplied to both electrodes and the catalytic metal is heated, heat is released due to resistance while passing through both electrodes; therefore, a temperature difference occurs in which the temperature decreases rapidly toward the ends closer to the electrodes than in the middle area of the catalytic metal, which is the farthest position from the electrodes, and ultimately, there was a problem in making it difficult to synthesize graphene of a uniform shape.

In order to solve this problem, a new structure and way of graphene production method and device for compensating for the temperature difference of a catalytic metal passing through both electrodes for Joule heating are presented in Korean Patent Publication No. 2173057.

FIG. 1 is an example view for explaining a conventional graphene manufacturing method and device, and FIG. 2 is a view for explaining a temperature profile by position according to a movement path of a catalytic metal passing between a first electrode roller and a second electrode roller in a conventional graphene manufacturing method and device.

Referring to FIG. 1 and FIG. 2, Prior Registration U.S. Pat. No. 2,173,057 basically provides a roll-to-roll method that enables continuous graphene synthesis while winding a catalytic metal M around a roll, and in particular, the catalytic metal M passing through an area between a first electrode roller 10 and a second electrode roller 20 extends downward by the own weight thereof, so as to have a U-shaped synthesis area M1 where two end areas adjacent to the first electrode roller 10 and the second electrode roller 20 face each other.

Since the synthesis area M1 of the catalytic metal M is provided with a temperature compensation area TCS in an inner space where end areas on both sides adjacent to the first electrode roller 10 and the second electrode roller 20 face each other, the temperature of the end areas on both sides of the synthesis area M1 substantially increases while exchanging radiant heat between the end areas on both sides of the synthesis area M1, thereby obtaining a uniform temperature profile overall along the longitudinal direction of the synthesis area M1. In addition, the synthesis area M1 may maintain a high temperature profile (T1<T2) overall due to the greenhouse effect in the temperature compensation area TCS.

However, the graphene manufacturing method and manufacturing device presented in Prior Registration U.S. Pat. No. 2,173,057 have a problem in that the quality of graphene synthesized in a roll-to-roll graphene manufacturing process deteriorates or a roll-to-roll continuous process is not properly performed.

Specifically, referring to FIG. 1, the catalytic metal M transferred while being released in a first rotational direction R1 from a supply roller rotates in the first rotational direction R1 by the first electrode roller 10 and moves downward, thereby forming the U-shaped synthesis area M1, wherein in an X area where the catalytic metal M moving to the lower section of the synthesis area M1 rotates in a second rotational direction R2 opposite to the first rotational direction R1 of the first electrode roller 10, stress is concentrated, causing excessive deformation.

Specifically, the catalytic metal M wound around the supply roller passes through the supply roller and the first electrode roller 10 that rotate in the same rotational direction, the first rotational direction R1, and the longitudinal and transverse direction cross sectional shapes of the synthesis area M1 of the catalytic metal M become convex toward the temperature compensation area TCS, and thereafter, the catalytic metal M that is continuously transferred is rotated in the second rotational direction R2 in the lower section of the synthesis area M1, so that the longitudinal and transverse direction cross sectional shapes are transformed into concave shapes toward the temperature compensation area TCS. Likewise, during the roll-to-roll transfer process, in the X area where the longitudinal direction cross sectional shape of the synthesis area M1 changes from a convex cross sectional shape to a concave cross sectional shape, or the curvature of the transverse direction cross sectional shape of the synthesis area M1 is rapidly deformed, stress is concentrated, and as a result, the position of the catalytic metal M being transferred roll-to-roll is distorted or a part thereof is folded, making it impossible to maintain the U-shaped synthesis area M1 stably.

Likewise, if the U-shaped synthesis area M1 of the catalytic metal M being transferred from roll-to-roll is not guaranteed, the temperature compensation and greenhouse effect by the U-shaped synthesis area M1 cannot be exerted at all, and this causes a problem in which the quality of the graphene synthesized with the catalytic metal M is significantly deteriorated.

In particular, when the catalytic metal M of the thin plate structure is Joule heated in a high temperature over 1000 degrees environment, a relatively large amount of deformation occurs in the U-shaped synthesis area M1, causing the position of the catalytic metal M to be distorted or folded, making it impossible to perform the roll-to-roll continuous process, and the quality and yield of the synthesized graphene are also significantly reduced.

### DETAILED DESCRIPTION OF THE INVENTION

### Technical Problem

An aspect of the present invention is to provide a Joule heating-based roll-to-roll graphene manufacturing method and a graphene manufacturing device capable of improving the quality and yield of synthesized graphene by ensuring stable roll-to-roll transfer of a catalytic metal having a temperature compensation area to a synthesis area and suppressing stress concentration occurring in the catalytic metal being transferred roll-to-roll by maintaining a concave shape toward the temperature compensation area without deformation of the longitudinal direction cross section or the transverse direction cross section of the catalytic metal while passing between a first roller part and a second roller part.

The aspect of the present invention is not limited to that mentioned above, and other aspects not mentioned will be clearly understood by those skilled in the art from the description below.

### Technical Solution

According to an embodiment of the present invention, a Joule heating-based roll-to-roll graphene manufacturing method relates to a method for manufacturing graphene using a Joule heating-based roll-to-roll graphene manufacturing apparatus including a first roller part and a second roller part for Joule heating a catalytic metal, and includes: a current supply step of supplying current to the first roller part and the second roller part; and a transfer step of transferring the catalytic metal, wherein the transfer step includes a synthesis area transfer step in which the catalytic metal passing through a temperature compensation area, which is an area between the first roller part and the second roller part, is transferred while maintaining a synthesis area extending downward due to the own weight thereof, and the synthesis area is transferred in a state of maintaining a concave shape toward the temperature compensation area without a cross section distorted in the longitudinal direction.

In the Joule heating-based roll-to-roll graphene manufacturing method according to an embodiment of the present invention, the first roller part may include a first upper roller and a first lower roller arranged on the opposite side of the first upper roller with the catalytic metal therebetween, the transfer step may further include a synthesis area entry step in which the longitudinal direction cross section shape of the catalytic metal entering the temperature compensation area becomes a concave shape toward the temperature compensation area, and the synthesis area entry step may be such that one surface of the catalytic metal wraps around a part of the first upper roller and rotates in a first rotational direction, and then the other surface of the catalytic metal wraps around a part of the first lower roller and rotates in a second rotational direction opposite to the first rotational direction.

In the Joule heating-based roll-to-roll graphene manufacturing method according to an embodiment of the present invention, the second roller part may include a second upper roller and a second lower roller arranged on the opposite side of the second upper roller with the catalytic metal therebetween, and the transfer step may further include a synthesis area release step in which one surface of the catalytic metal is rotated in the second rotational direction while wrapping around a part of the second lower roller, and then the other surface of the catalytic metal is rotated in the first rotational direction while wrapping around a part of the second upper roller, thereby releasing the catalytic metal from the temperature compensation area.

In the Joule heating-based roll-to-roll graphene manufacturing method according to an embodiment of the present invention, in the synthesis area release step, the second upper roller and the second lower roller may be arranged in an idle state with the catalytic metal therebetween.

In the Joule heating-based roll-to-roll graphene manufacturing method according to an embodiment of the present invention, in the synthesis area entry step, the first upper roller and the first lower roller may be pressed with a first pressure with the catalytic metal therebetween, and in the synthesis area release step, the second upper roller and the second lower roller may be pressed with a second pressure less than the first pressure with the catalytic metal therebetween.

According to another embodiment of the present invention, a Joule heating-based roll-to-roll graphene manufacturing method includes: a current supply step of supplying current to the first roller part and the second roller part; and a transfer step of transferring the catalytic metal, wherein the transfer step includes a synthesis area transfer step in which the catalytic metal passing through a temperature compensation area, which is an area between the first roller part and the second roller part, is transferred while maintaining a synthesis area extending downward due to the own weight thereof, and the synthesis area is transferred in a state in which a cross section in the transverse direction maintains a concave shape toward the temperature compensation area.

Meanwhile, according to an embodiment of the present invention, a Joule heating-based roll-to-roll graphene manufacturing apparatus is a Joule heating-based roll-to-roll graphene manufacturing apparatus that supports a catalytic metal and is supplied with current to perform Joule heating so that graphene is synthesized with one surface of the catalytic metal, and includes: a first roller part supporting the catalytic metal; and a second roller part arranged apart from the first roller part in the transfer direction of the catalytic metal, wherein the catalytic metal has a synthesis area extending downward due to the own weight thereof while passing through a temperature compensation area, which is an area between the first roller part and the second roller part, and the synthesis area maintains a concave shape toward the temperature compensation area without a cross section distorted in the longitudinal direction.

In the Joule heating-based roll-to-roll graphene manufacturing apparatus according to an embodiment of the present invention, the first roller part may include: a first upper roller that contacts and supports the other surface of the catalytic metal and causes the catalytic metal to rotate in a first rotational direction; and a first lower roller that is arranged on the opposite side of the first upper roller with the catalytic metal therebetween, contacts and supports one surface of the catalytic metal, and causes the catalytic metal that has passed through the first upper roller to rotate in a second rotational direction opposite to the first rotational direction and enter the temperature compensation area.

In the Joule heating-based roll-to-roll graphene manufacturing apparatus according to an embodiment of the present invention, the second roller part may include: a second lower roller that contacts and supports one surface of the catalytic metal and causes the catalytic metal to rotate in the second rotational direction; and a second upper roller that is arranged on the opposite side of the second lower roller with the catalytic metal therebetween, contacts and supports the other surface of the catalytic metal, and causes the catalytic metal that has passed through the second lower roller to rotate in the first rotational direction and be released from the temperature compensation area.

In the Joule heating-based roll-to-roll graphene manufacturing apparatus according to an embodiment of the present invention, the first roller part may further include a first gap adjustment part that adjusts the gap between the first upper roller and the first lower roller, and the second roller part may further include a second gap adjustment part that adjusts the gap between the second upper roller and the second lower roller.

In the Joule heating-based roll-to-roll graphene manufacturing apparatus according to an embodiment of the present invention, the first gap adjustment part may include a first elastic member that elastically supports the first upper roller or the first lower roller so that the catalytic metal passing between the first upper roller and the first lower roller is pressed with a first pressure, and the second gap adjustment part may include a second elastic member that elastically supports the second upper roller or the second lower roller so that the catalytic metal passing between the second upper roller and the second lower roller is pressed with a second pressure less than the first pressure.

The Joule heating-based roll-to-roll graphene manufacturing apparatus according to an embodiment of the present invention may further include: a chamber having an internal space of a vacuum atmosphere; a supply part for unwinding the catalytic metal wound around a supply roller to be supplied to the first roller part; and a recovery part for recovering the catalytic metal synthesized with graphene released from the second roller part while being wound around a recovery roller, wherein the supply roller, the first roller part, the second roller part, and the recovery roller are arranged in the internal space.

In the Joule heating-based roll-to-roll graphene manufacturing apparatus according to an embodiment of the present invention, the supply roller, the first roller part, the second roller part, and the recovery roller may include a material that suppresses outgassing in a vacuum atmosphere.

In the Joule heating-based roll-to-roll graphene manufacturing apparatus according to an embodiment of the present invention, the supply roller, the first roller part, the second roller part, and the recovery roller may each have a roller width corresponding to the width of the catalytic metal, and the roller width may gradually increase in the direction of the supply roller, the first roller part, the second roller part, and the recovery roller.

According to another embodiment of the present invention, a Joule heating-based roll-to-roll graphene manufacturing apparatus includes: a first roller part supporting a catalytic metal; and a second roller part arranged apart from the first roller part in the transfer direction of the catalytic metal, wherein the catalytic metal has a synthesis area extending downward due to the own weight thereof while passing through a temperature compensation area, which is an area between the first roller part and the second roller part, and a cross section in the transverse direction of the synthesis area maintains a concave shape toward the temperature compensation area.

### Advantageous Effects

According to the present invention, while passing through a temperature compensation area between a first roller part and a second roller part, the longitudinal direction cross section or the transverse direction cross section of a catalytic metal is not deformed and maintains a concave shape toward the temperature compensation area, thereby suppressing concentrated stress and deformation occurring in the catalytic metal during a roll-to-roll process and stably maintaining a roll-to-roll transfer path for a synthesis area that is arranged to extend downward for temperature compensation. Accordingly, the quality and yield of synthesized graphene can be greatly improved.

The effects of the present invention are not limited to the effects described above, and should be understood to include all effects that are inferable from the configuration of the present invention described in the detailed description or claims of the present invention.

### BRIEF DESCRIPTION OF THE DRAWINGS

FIG. 1 is an example view for explaining a conventional graphene manufacturing method and device.

FIG. 2 is each a view for explaining a temperature profile by position according to a movement path of a catalytic metal passing between a first electrode roller and a second electrode roller in a conventional graphene manufacturing method and device.

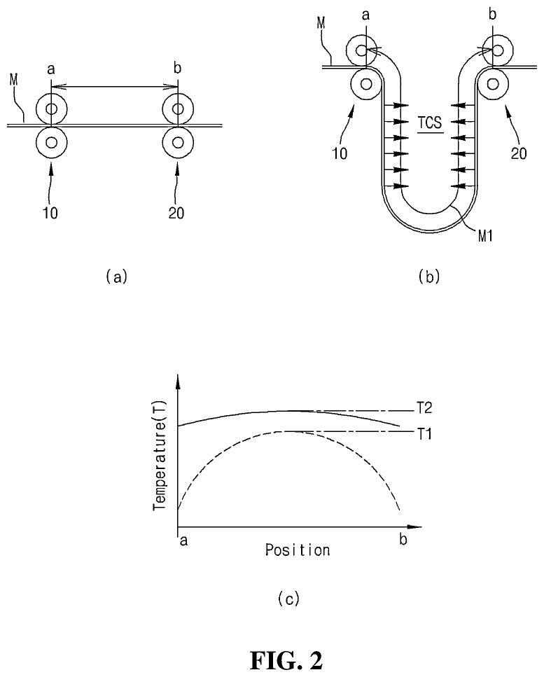

FIG. 3 is an example view showing a graphene manufacturing device according to an embodiment of the present invention.

FIG. 4 is an enlarged partial view showing a synthesis area of a catalytic metal of FIG. 3.

FIG. 5 is an enlarged partial view showing a first roller part of FIG. 4.

FIG. 6 is a partial example view showing a gap adjustment part of a graphene manufacturing device according to an embodiment of the present invention.

FIG. 7 is each an example view showing whether a first roller part and a second roller part are forced to rotate and various modified examples of a gap adjustment part according to an embodiment of the present invention.

FIG. 8 is a planar example view of FIG. 3.

### MODE FOR CARRYING OUT THE INVENTION

Hereinafter, preferred embodiments of the present invention, which can specifically solve the

problems to be solved as described above, are described with reference to the accompanying drawings. In describing these embodiments, the same names and symbols may be used for the same components, and additional descriptions thereof may be omitted.

For convenience of explanation, a Joule heating-based roll-to-roll graphene manufacturing apparatus according to an embodiment of the present invention will first be described, and then a Joule heating-based roll-to-roll graphene manufacturing method according to an embodiment of the present invention will be described.

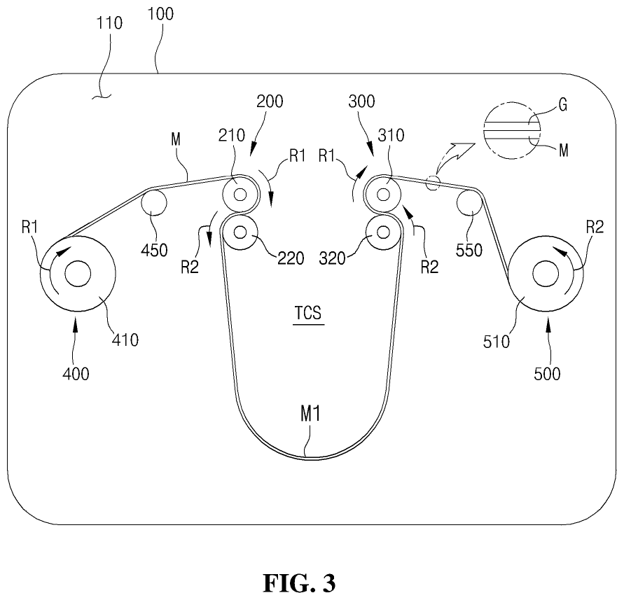

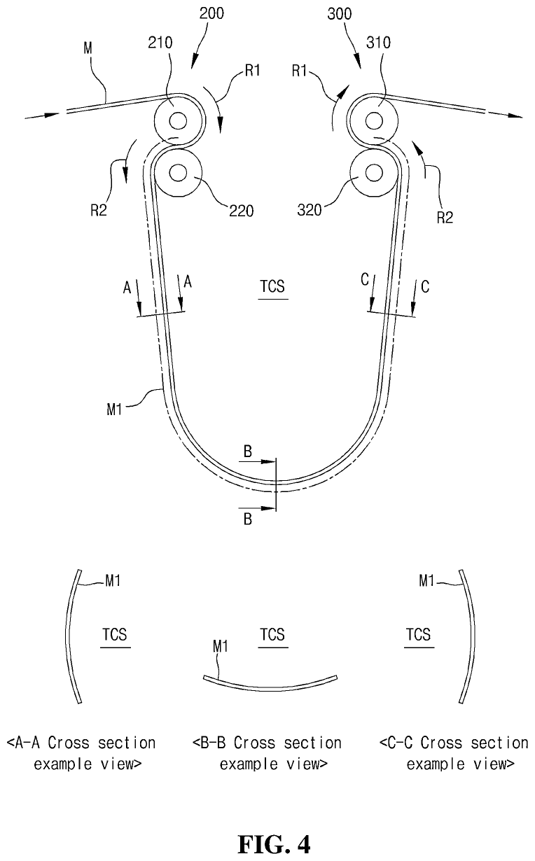

FIG. 3 is an example view showing a graphene manufacturing device according to an embodiment of the present invention, and FIG. 4 is an enlarged partial view showing a synthesis area of a catalytic metal of FIG. 3.

Referring to FIGS. 3 and 4, the graphene manufacturing device according to the present embodiment may include a chamber 100, a supply part 400, a first roller part 200, a second roller part 300, and a recovery part 500.

The chamber 100 is provided with an internal space 110 for forming graphene G.

The internal space 110 may be provided with a gas discharge port through which a reaction gas for synthesizing graphene G may be introduced and a used gas is discharged. Such a reaction gas is not particularly limited.

In addition, the internal space 110 may be formed into a vacuum atmosphere for graphene G synthesis. That is, the internal space 110 may be formed into a vacuum atmosphere by a vacuum pump. The supply part 400, the first roller part 200, the second roller part 300, and the recovery part 500 may all be placed in a vacuum atmosphere.

The supply part 400 supplies a catalytic metal M for graphene G synthesis and may be placed in the internal space 110.

The supply part 400 may have a supply roller 410. That is, as the supply roller 410 rotates, the catalytic metal M wrapped around the supply roller 410 may be released and supplied toward the first roller part 200.

Since the supply roller 410 may be in direct contact with the catalytic metal M that is Joule heated, the part that comes into contact with the catalytic metal M may be made of an insulating material.

In addition, the supply roller 410 may include a material that suppresses outgassing in a vacuum atmosphere. For example, the supply roller 410 may be made of polyetheretherketone (PEEK), a representative functional polymer material.

If the supply roller 410 is made of a material that suppresses outgassing in a vacuum atmosphere, the outgassing effect in which some substances of the supply roller 410 are vaporized or sublimated in a vacuum atmosphere may be prevented, thereby preventing the cleanliness of the internal space 110 from being lowered by impurities, and thus the quality and yield of graphene G may be improved. In addition, since the vacuum atmosphere of the internal space 110 may be formed in a short time, the process time may be shortened.

The recovery part 500 recovers the catalytic metal M synthesized with graphene G, and may be placed in the internal space 110 like the supply part 400.

The recovery part 500 may have a recovery roller 510. That is, the catalytic metal M synthesized with graphene G released from the second roller part 300 after passing through the temperature compensation area TCS may be recovered while being wound around the recovery roller 510.

Since the recovery roller 510 may be in direct contact with the catalytic metal M that is Joule heated like the supply roller 410, the part that comes into contact with the catalytic metal M may be made of an insulating material.

In addition, the recovery roller 510 may include a material that suppresses outgassing in a vacuum atmosphere like the supply roller 410, and may be composed of the same material as the supply roller 410.

The supply roller 410 and the recovery roller 510 may be rotated at the same rotational speed, and accordingly, the catalytic metal M may pass through the temperature compensation area TCS at a uniform moving speed.

In addition, the supply roller 410 and the recovery roller 510 may be rotated in the same rotational direction, or may be rotated in opposite directions as shown.

In addition, the supply roller 410 may be in an idle state, and the recovery roller 510 may be forcibly rotated. That is, the catalytic metal M wound around the supply roller 410 may be released by the rotational force of the recovery roller 510.

Of course, both the supply roller 410 and the recovery roller 510 may be forcibly rotated, and at this time, the supply roller 410 and the recovery roller 510 may be independently controlled. That is, the supply part 400 and the recovery part 500 may independently adjust the rotational speeds of the supply roller 410 and the recovery roller 510 to adjust the supply and recovery speeds of the catalytic metal M, and accordingly, the synthesis time of the graphene G synthesized with the catalytic metal M may be adjusted and set. In addition, by independently adjusting the rotation speeds of the supply roller 410 and the recovery roller 510, the tension of the catalytic metal M passing through an area between the supply part 400 and the first roller part 200 may be adjusted, and the tension of the catalytic metal M passing through an area between the second roller part 300 and the recovery part 500 may be adjusted. In addition, by independently adjusting the rotation speeds of the supply roller 410 and the recovery roller 510, the length of a synthesis area M1 of the catalytic metal M passing through the temperature compensation area TCS between the first roller part 200 and the second roller part 300 may be changed, for example, by lengthening or shortening the synthesis area M1.

Meanwhile, the graphene manufacturing device may further include a first guide roller 450 and a second guide roller 550.

The first guide roller 450 may be placed in an area between the supply roller 410 and the first roller part 200, and may guide the catalytic metal M transferred from the supply roller 410 toward the first roller part 200. At this time, by changing the position of the first guide roller 450, the tension of the catalytic metal M transferred from the supply roller 410 toward the first roller part 200 may be adjusted.

The second guide roller 550 may be placed in an area between the second roller part 300 and the recovery roller 510, and may guide the catalytic metal M synthesized with graphene G transferred from the second roller part 300 toward the recovery roller 510. At this time, by changing the position of the second guide roller 550, the tension of the catalytic metal M synthesized with graphene G transferred from the second roller part 300 toward the recovery roller 510 may be adjusted.

The first roller part 200 and the second roller part 300 are arranged apart from each other in the transfer direction of the catalytic metal M in the internal space 110 and may support the catalytic metal M being transferred.

The first roller part 200 and the second roller part 300 may include a material that suppresses outgassing in a vacuum atmosphere, like the supply roller 410 and the recovery roller 510.

The first roller part 200 and the second roller part 300 may receive current from an external power supply part (not shown) for graphene G synthesis and Joule heat the catalytic metal M.

Ultimately, the first roller part 200 and the second roller part 300 are configured to support the catalytic metal M and at the same time, to be in close contact with the catalytic metal M, so that current for Joule heating may be supplied to the catalytic metal M. Ultimately, graphene G may be synthesized in the catalytic metal M passing through the temperature compensation area TCS, which is the area between the first roller part 200 and the second roller part 300.

At this time, the catalytic metal M passing through the temperature compensation area TCS, which is the area between the first roller part 200 and the second roller part 300, may have a U-shaped or horseshoe-shaped synthesis area M1 facing one surface where graphene G is synthesized by extending downward by the own weight thereof. That is, the catalytic metal M entering the temperature compensation area TCS extends downward by the own weight thereof after passing the first roller part 200, and then moves upward toward the second roller part 300, thereby forming a U-shaped or horseshoe-shaped synthesis area M1 where one surface synthesized with graphene G faces the other.

Here, the synthesis area M1 is a part of the catalytic metal M that extends downward by the own weight thereof while passing between the first roller part 200 and the second roller part 300.

That is, the synthesis area M1 may correspond to the area from a separation point where the catalytic metal M is separated from the first roller part 200 to a contact point where the catalytic metal M comes into contact with the second roller part 300.

In addition, as will be described later, the synthesis area M1 may correspond to an area from a first point of the catalytic metal M that is in contact with a first upper roller 210 and a first lower roller 220 at the same time to a second point of the catalytic metal M that is in contact with a second upper roller 310 and a second lower roller 320 at the same time.

The synthesis area M1 of the catalytic metal M, which extends downward by the own weight thereof and has the temperature compensation area TCS formed in the inner space, exchanges radiant heat between two end areas adjacent to the first roller part 200 and the second roller part 300. As a result, the temperature of the two end areas of the synthesis area M1 that face each other substantially increases, so that an overall uniform temperature profile may be obtained along the longitudinal direction of the synthesis area M1. In addition, the synthesis area M1 may maintain a high temperature profile overall due to the greenhouse effect in the temperature compensation area TCS.

According to the present embodiment, the synthesis area M1 of the catalytic metal M passing through an area between the first roller part 200 and the second roller part 300 may maintain a concave shape toward the temperature compensation area TCS without a longitudinal direction cross section being distorted. In addition, the transverse direction cross section of the synthesis area M1 of the catalytic metal M may also maintain a concave shape toward the temperature compensation area TCS.

The first roller part 200 therefor may include the first upper roller 210 and the first lower roller 220.

The first upper roller 210 may contact and support the catalytic metal M transferred from the supply roller 410.

The first upper roller 210 may rotate in a first rotational direction R1 and rotate the catalytic metal M transferred from the supply roller 410 in the first rotational direction R1.

The first lower roller 220 may be arranged on the opposite side of the first upper roller 210 with the catalytic metal M therebetween, and may be arranged on the lower side of the first upper roller 210. The first lower roller 220 may contact and support the catalytic metal M transferred through the first upper roller 210.

The first lower roller 220 may rotate in a second rotational direction R2 opposite to the first rotational direction R1 and rotate the catalytic metal M transferred through the first upper roller 210 in the second rotational direction R1.

The catalytic metal M enters the temperature compensation area TCS forming the synthesis area M1 while passing through the first upper roller 210 and the first lower roller 220 sequentially, wherein in the process of passing thereof through the first upper roller 210 and the first lower roller 220 sequentially, the longitudinal direction cross section and the transverse direction cross section of the synthesis area M1 may be transformed into a concave shape toward the temperature compensation area TCS.

At this time, a start point where the longitudinal direction cross section of the synthesis area M1 is transformed into a concave shape toward the temperature compensation area TCS may correspond to the first point of the catalytic metal M that is in contact with the first upper roller 210 and the first lower roller 220 at the same time. As a result, the longitudinal direction cross section and the transverse direction cross section of the catalytic metal M may maintain a concave shape toward the temperature compensation area TCS from the first point where the synthesis area M1 begins.

At least one of the first upper roller 210 and the first lower roller 220 may receive current from a power supply part to heat the catalytic metal M. For example, only the roller that comes into contact with the catalytic metal M over a relatively large area among the first upper roller 210 and the first lower roller 220 may be configured to heat the catalytic metal M. The first upper roller 210 and the first lower roller 220 may be composed of copper.

The second roller part 300 may include the second lower roller 320 and the second upper roller 310.

The second lower roller 320 may contact and support the catalytic metal M that has passed through the first lower roller 220.

The second lower roller 320 may rotate in the second rotational direction R2 and rotate the catalytic metal M that has passed through the first lower roller 220 in the second rotational direction R2.

The second upper roller 310 may be arranged on the opposite side of the second lower roller 320 with the catalytic metal M therebetween, and may be arranged on the upper side of the second lower roller 320. The second upper roller 310 may contact and support the catalytic metal M that is transferred through the second lower roller 320.

The second upper roller 310 may rotate in the first rotational direction R1 so that the catalytic metal M transferred after passing through the second lower roller 320 faces the direction of the recovery part 500.

The catalytic metal M may be released from the temperature compensation area TCS forming the synthesis area M1 while passing through the second lower roller 320 and the second upper roller 310 sequentially, and until passing thereof through the second upper roller 310, the longitudinal direction cross section and the transverse direction cross section of the synthesis area M1 may continuously maintain a concave shape toward the temperature compensation area TCS.

At this time, an end point where the longitudinal direction cross section of the synthesis area M1 is maintained in a concave shape toward the temperature compensation area TCS may correspond to the second point of the catalytic metal M that is in contact with the second upper roller 310 and the second lower roller 320 at the same time.

At least one of the second upper roller 310 and the second lower roller 320 may receive current from a power supply part to heat the catalytic metal M. For example, only the roller that is in contact with the catalytic metal M over a relatively large area among the second upper roller 310 and the second lower roller 320 may be configured to heat the catalytic metal M. The second upper roller 310 and the second lower roller 320 may be made of copper.

As described above, the catalytic metal M existing in a roll-to-roll transfer section connecting the first point of the catalytic metal M that is in simultaneous contact with the first upper roller 210 and the first lower roller 220 to the second point of the catalytic metal M that is in simultaneous contact with the second upper roller 310 and the second lower roller 320 in the synthesis area M1 may have the longitudinal direction cross section and the transverse direction cross section continuously maintained in a concave shape toward the temperature compensation area TCS.

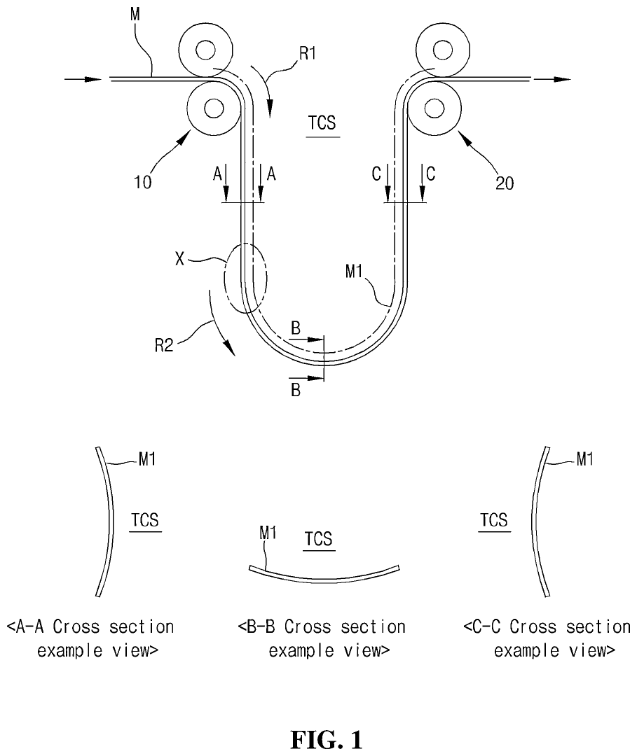

By maintaining the longitudinal direction cross section and the transverse direction cross section of the synthesis area M1 being transferred roll-to-roll to have a concave shape toward the temperature compensation area TCS, the stress generation in the X area (see FIG. 1) that rotates the lower section of the synthesis area M1 in the second rotational direction R2 may be suppressed, and the position of the catalytic metal M may be prevented from being distorted or folded in the entire section of the synthesis area M1 including the X area. As a result, the U-shaped or horseshoe-shaped synthesis area M1 may be stably maintained during a roll-to-roll transfer process.

Meanwhile, the first roller part 200 may further include a first roller driving part.

That is, the first upper roller 210 and the first lower roller 220 may be installed in a state of being freely rotatable, but may be configured to be forcibly rotated by the first roller driving part. In this case, the catalytic metal M wound around the first supply roller 410 may be released and transferred toward the first roller part 200 by the rotational force of the first roller part 200. At this time, the first roller driving part may be synchronized with the recovery part 500. In addition, when forced to rotate by the first roller driving part, one of the first upper roller 210 and the first lower roller 220 may be a driving shaft and the other may be a driven shaft.

In addition, the first roller part 200 may further include a first close contact roller.

The first close contact roller may be in close contact with the outer surface of the first upper roller 210 with the catalytic metal M therebetween, and accordingly, the catalytic metal M that is in contact and supported while wrapping a part of the first upper roller 210 may be suppressed from being lifted from the first upper roller 210.

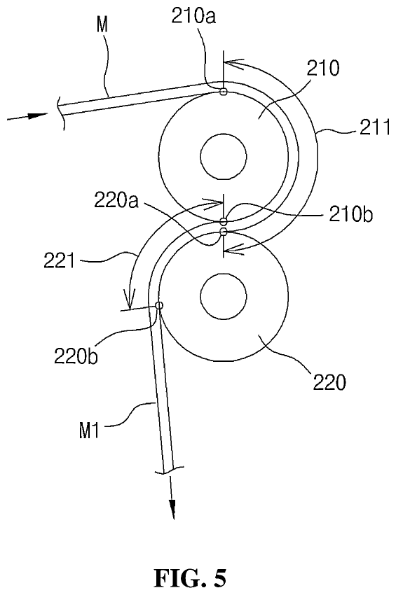

Referring to FIG. 5, the contact state of the catalytic metal M by the first roller part 200 will be supplemented as follows.

The first upper roller 210 may have an arc-shaped first contact support part 211 having a first contact start point 210a with which one surface of the catalytic metal M comes into contact and a first contact end point 210b from which the one surface of the catalytic metal M is separated.

The first lower roller 220 may have a second contact support portion 221 in the shape of an arc having a second contact start point 220a with which the other surface of the catalytic metal M comes into contact and a second contact end point 220b from which the other surface of the catalytic metal M is separated.

At this time, the first contact end point 210b and the second contact point 220a may be arranged on a vertical line connecting the rotation axis of the first upper roller 210 and the rotation axis of the first lower roller 220, and the first contact end point 210b and the second contact start point 220a may simultaneously come into contact with the one surface and the other surface of the catalytic metal M. Here, the first contact end point 210b and the second contact start point 220a may correspond to a start point of the synthesis area M1 that is transformed into a concave shape toward the temperature compensation area TCS.

Meanwhile, the second roller part 300 may further include a second roller driving part.

That is, the second upper roller 310 and the second lower roller 320 may be installed in a state of being freely rotatable, but may also be configured to be forcedly rotated by the second roller driving part. In this case, the second roller driving part may be synchronized with the first roller driving part and the recovery part 500. In addition, when forcedly rotated by the second roller driving part, one of the second upper roller 310 and the second lower roller 320 may be a driving shaft and the other may be a driven shaft.

In addition, the second roller part 300 may further include a second close contact roller.

The second close contact roller may be in close contact with the outer surface of the second upper roller 310 with the catalytic metal M therebetween, and accordingly, the catalytic metal M that is in contact and supported while wrapping a part of the second upper roller 310 may be suppressed from being lifted from the second upper roller 310.

Meanwhile, the rotation speeds of the first roller part 200 and the second roller part 300 may be independently controlled by the first roller driving part and the second roller driving part, and the length and height of the synthesis area M1 may be adjusted by controlling the rotation speeds of the first roller part 200 and the second roller part 300 differently from each other.

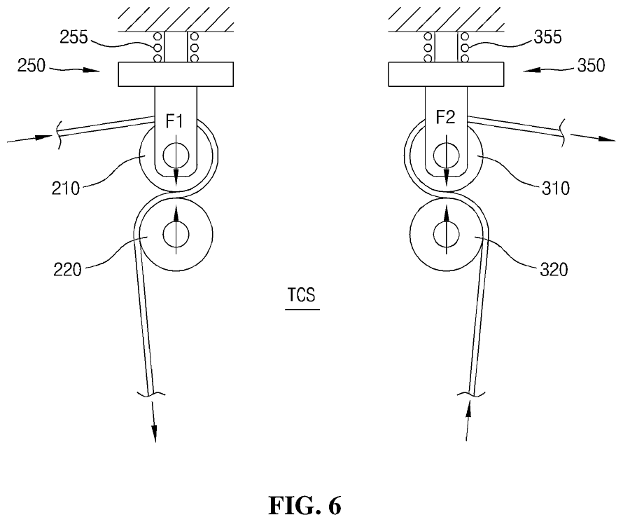

FIG. 6 is a partial example view showing a gap adjustment part of a graphene manufacturing device according to an embodiment of the present invention.

Referring to FIG. 6, the first roller part 200 may further include a first gap adjustment part 250.

The first gap adjustment part 250 may connect the first upper roller 210 and the first lower roller 220, and adjust the gap between the first upper roller 210 and the first lower roller 220. For example, the first gap adjustment part 250 may have one end connected to the rotation axis of the first upper roller 210, and the other end connected to the rotation axis of the first lower roller 220. At this time, the rotation axis of the first upper roller 210 or the rotation axis of the first lower roller 220 may be configured to be slidable. Therefore, the first gap adjustment part 250 may adjust the gap between the first upper roller 210 and the first lower roller 220 by moving the first upper roller 210 and the first lower roller 220 closer or further apart in the vertical direction. The first gap adjustment part 250 according to an embodiment may move the first upper roller 210 downward toward the first lower roller 220 of which the position is fixed.

In addition, the first gap adjustment part 250 may further include a first elastic member 255.

The first elastic member 255 may elastically support the first upper roller 210 or the first lower roller 220 with a first pressure F1. Therefore, the catalytic metal M passing between the first upper roller 210 and the first lower roller 220 may be pressed by the first pressure F1 and may come into more close contact with the first upper roller 210 and the first lower roller 220. The elastic restoring force of the first elastic member 255 may be adjusted, and the first pressure F1 may be changed by adjusting the elastic restoring force of the first elastic member 255.

The second roller part 300 may further include a second gap adjustment part 350.

The second gap adjustment part 350 may connect the second upper roller 310 and the second lower roller 320, and may adjust the gap between the second upper roller 310 and the second lower roller 320. This second gap adjustment part 350 may be configured in the same manner as the first gap adjustment part 250 described above.

In addition, the second gap adjustment part 350 may further include a second elastic member 355.

The second elastic member 355 may elastically support the second upper roller 310 or the second lower roller 320 with a second pressure F2. Therefore, the catalytic metal M passing between the second upper roller 310 and the second lower roller 320 may be pressed by the second pressure F2 and may come into more close contact with the second upper roller 310 and the second lower roller 320. The elastic restoring force of the second elastic member 355 may be adjusted, and the second pressure F2 may be changed by adjusting the elastic restoring force of the second elastic member 355.

According to the present embodiment, the second pressure F2 is preferably smaller than the first pressure F1. That is, the first roller part 200 allows the catalytic metal M before synthesis of the graphene G to pass through, and the second roller part 300 allows the catalytic metal M synthesized with the graphene G to pass through. In this way, if the first upper roller 210 and the first lower roller 220 are contacted with the relatively strong first pressure F1 for the catalytic metal M passing through the first roller part 200, the transfer of the catalytic metal M may be guided more smoothly. In addition, if the second upper roller 310 and the second lower roller 320 are contacted with the relatively small second pressure F2 for the catalytic metal M passing through the second roller part 300, the graphene G synthesized with one surface of the catalytic metal M may be prevented from being damaged.

In addition, since the gap between the first upper roller 210 and the first lower roller 220 and the gap between the second upper roller 310 and the second lower roller 320 may be appropriately adjusted according to the thickness of the catalytic metal M or the catalytic metal M synthesized with graphene G, it is possible to ensure more stable roll-to-roll transfer for catalytic metals M and catalytic metals M synthesized with graphene G, having various thicknesses.

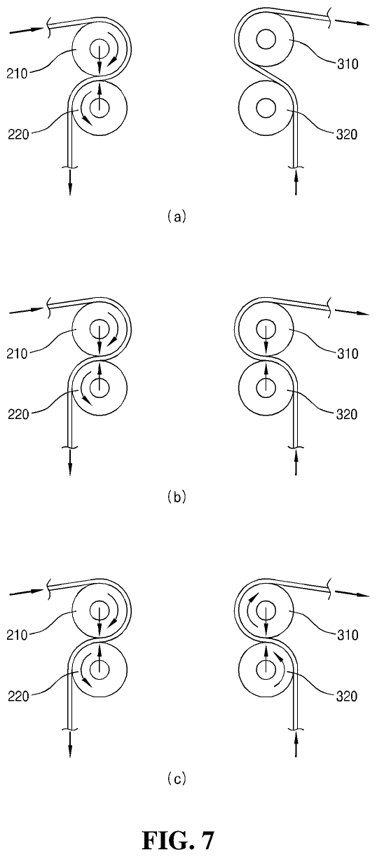

FIG. 7 is an example view showing whether a first roller part and a second roller part are forced to rotate and various modified examples of a gap adjustment part according to an embodiment of the present invention.

First, referring to (a), (b), and (c) of FIG. 7, the first upper roller 210 and the first lower roller 220 of the first roller part 200 may be configured to be forcibly rotated by the first roller driving part, and at the same time, the first upper roller 210 and the first lower roller 220 may be arranged in close contact with each other with the catalytic metal M interposed therebetween by the first gap adjustment part 250 (see FIG. 6) having the first elastic member 255 (see FIG. 6).

At this time, referring to (a) of FIG. 7, the second upper roller 310 and the second lower roller

320 of the second roller part 300 may be configured in an idle state in which free rotation is possible, and at the same time, the second upper roller 310 and the second lower roller 320 may be arranged with the gap wider than the thickness of the catalytic metal M synthesized with the graphene G by the second gap adjustment part 350 (see FIG. 6).

In addition, referring to (b) of FIG. 7, the second upper roller 310 and the second lower roller 320 of the second roller part 300 may be configured in an idle state in which free rotation is possible, and at the same time, the second upper roller 310 and the second lower roller 320 may be arranged in close contact with each other with the catalytic metal M synthesized with the graphene therebetween by the second gap adjustment part 350 having the second elastic member 355 (see FIG. 6).

In addition, referring to (c) of FIG. 7, the second upper roller 310 and the second lower roller 320 of the second roller part 300 may be configured to be forcibly rotated by the second roller driving part, and at the same time, the second upper roller 310 and the second lower roller 320 may be arranged in close contact with each other with the catalytic metal M synthesized with the graphene G therebetween by the second gap adjustment part 350 having the second elastic member 355.

As in FIG. 7, by adjusting and setting the forced rotation and elastic pressurization of the first roller part 200 and the second roller part 300 differently, the amount of change, such as a change in the cross sectional shape or elongation of the catalytic metal M passing through the temperature compensation area TCS, may be effectively reduced. Accordingly, the catalytic metal M passing through the temperature compensation area TCS may be prevented from being distorted or folded, thereby ensuring the position stability of the U-shaped or horseshoe-shaped synthesis area M1 during a roll-to-roll process.

Likewise, whether the first roller part 200 and the second roller part 300 are forced to rotate or elastically pressed may be selected from one of the forms, FIG. 7, depending on the type of catalytic metal M used and the environment formed in the internal space 110.

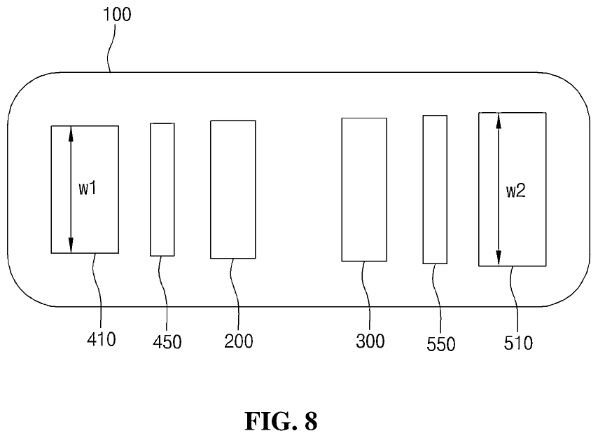

Meanwhile, FIG. 8 is a planar example view of FIG. 3.

Referring to FIG. 8, according to the present embodiment, each of the supply roller 400, the first roller part 200, the second roller part 300, and the recovery roller 500, which are sequentially arranged in the transfer direction of the catalytic metal M, has a roller width corresponding to the width of the catalytic metal M, wherein at this time, it is preferable that the roller width of each roller gradually increases (w1<w2) toward the supply roller 400, the first roller part 200, the second roller part 300, and the recovery roller 500.

Accordingly, even if the position of the catalytic metal M during roll-to-roll transfer is misaligned, the supply roller 400, the first roller part 200, the second roller part 300, and the recovery roller 500 may effectively guide the movement of the catalytic metal M, and thus, it is possible no to unnecessarily interrupt a roll-to-roll process.

Hereinafter, the Joule heating-based roll-to-roll graphene manufacturing method according to the present embodiment will be described.

The Joule heating-based roll-to-roll graphene manufacturing method according to the present embodiment may be basically performed using the Joule heating-based roll-to-roll graphene manufacturing apparatus described above.

Referring to FIG. 3, the Joule heating-based roll-to-roll graphene manufacturing method according to the present embodiment may include a current supply step and a transfer step.

The current supply step may be a step of supplying current to the first roller part 200 and the second roller part 300. That is, when current is supplied to the first roller part 200 and the second roller part 300, the catalytic metal M may be heated by Joule heating, and the graphene G may be synthesized with one surface of the heated catalytic metal M.

The transfer step may be a step of transferring the catalytic metal M. That is, as the catalytic metal M heated by Joule heating by the first roller part 200 and the second roller part 300 is transferred roll-to-roll, the graphene G may be continuously synthesized with one surface of the catalytic metal M.

The transfer step may include a synthesis area transfer step.

The synthesis area transfer step may be a step in which the transfer is made while maintaining maintaining the U-shaped or horseshoe-shaped synthesis area M1 where the catalytic metal M passing through the temperature compensation area TCS, which is the area between the first roller part 200 and the second roller part 300, extends downward due to the own weight thereof and one surface synthesized with the graphene G faces the other.

In this synthesis area transfer step, the synthesis area M1 of the catalytic metal M may be transferred while maintaining a concave shape toward the temperature compensation area TCS without the longitudinal direction cross section being deformed, and also maintaining a concave shape of the transverse direction cross section toward the temperature compensation area TCS.

The transfer step may further include a synthesis area entry step.

The synthesis area entry step may be a step in which the longitudinal direction cross section and the transverse direction cross section shape of the synthesis area M1 entering the temperature compensation area TCS, which is the area between the first roller part 200 and the second roller part 300, become concave toward the temperature compensation area TCS. That is, in the synthesis area entry step, the catalytic metal M may enter the temperature compensation area TCS while one surface wraps around a part of the first upper roller 210 and rotates in the first rotational direction R1, and then the other surface wraps around a part of the first lower roller 220 and rotates in the second rotational direction R2.

The transfer step may further include a synthesis area release step.

The synthesis area release step may be a step of guiding the catalytic metal M released from the temperature compensation area TCS, which is the area between the first roller part 200 and the second roller part 300. That is, in the synthesis area release step, the catalytic metal M may be released from the temperature compensation area TCS while one surface wraps around a part of the second lower roller 320 and rotates in the second rotational direction R2, and then the other surface wraps around a part of the second upper roller 310 and rotates in the first rotational direction R1.

In this transfer step, the longitudinal direction cross section and the transverse direction cross section of the synthesis area M1 may be transferred while maintaining a concave shape toward the temperature compensation area TCS. As a result, the U-shaped or horseshoe-shaped synthesis area M1 may be stably maintained without deformation such as position distortion or folding of the catalytic metal M being transferred roll-to-roll.

In the process of going through the transfer step, the graphene G is synthesized in the synthesis area M1 of the catalytic metal M, and the synthesis area M1 where the graphene G is synthesized may be continuously recovered while being wound around the recovery roller 510.

In this transfer step, at least one roller among the supply roller 410, the first roller part 200, the second roller part 300, and the recovery roller 510 may be forcibly rotated. For example, the catalytic metal M wrapped around the supply roller 410 by the rotational force of the forcibly rotated first roller part 200 may be transferred toward the first roller part 200 while being released, and the catalytic metal M synthesized with the graphene G may be recovered while being wrapped around the recovery roller 510 by the rotational force of the forcibly rotated recovery roller 510. That is, the first roller part 200 and the recovery roller 510 may be forcibly rotated by the roller driving part, and the supply roller 410 and the second roller part 300 may be in an idle state where free rotation is made.

In addition, the catalytic metal M may be pressed by the first roller part 200 and the second roller part 300 in the transfer step. Referring to FIG. 6, the elastic restoring force of the first elastic member 255 of the first gap adjustment part 250 may be adjusted so as to set the catalytic metal M passing between the first upper roller 210 and the first lower roller 220 to be pressed with the first pressure F1. In addition, the elastic restoring force of the second elastic member 355 of the second gap adjustment part 350 may be adjusted so as to set the catalytic metal M passing between the second upper roller 310 and the second lower roller 320 to be with the second pressure F2.

At this time, the first pressure F1 is set relatively high so that the first upper roller 210 and the first lower roller 220 contact the catalytic metal M passing through the first roller part 200 with the relatively strong first pressure F1, thereby smoothly guiding the transfer of the catalytic metal M. In addition, the second pressure F2 is set relatively smaller than the first pressure F1, so that the second upper roller 310 and the second lower roller 320 contact the catalytic metal M passing through the second roller part 300 with the relatively small second pressure F2, thereby preventing damage to the graphene G synthesized with one surface of the catalytic metal M.

Meanwhile, the Joule heating-based roll-to-roll graphene manufacturing method according to the present embodiment may further include a vacuum atmosphere creation step.

The vacuum atmosphere creation step may be performed before the current supply step, and may be a step of creating a vacuum atmosphere in the internal space 110 of the chamber 100.

When the internal space 110 of the chamber 100 is created as a vacuum atmosphere using a vacuum pump, a reaction gas for graphene G synthesis may be supplied to the internal space 110 of the chamber 100.

As described above, according to the present invention, the longitudinal direction cross section and the transverse direction cross section of the synthesis area M1 of the catalytic metal M passing between the first roller part 200 and the second roller part 300 maintain a concave shape toward the temperature compensation area TCS, thereby suppressing concentrated stress and deformation occurring in the catalytic metal M being transferred roll-to-roll, and stably maintaining the roll-to-roll transfer path of the synthesis area M1 that is arranged to extend downward for temperature compensation, and thus it is possible to significantly improve the quality and yield of the graphene G synthesized with the catalytic metal M.

Although the preferred embodiments of the present invention have been described with reference to the drawings as described above, it will be apparent to those skilled in the art that various modifications or changes may be made to the present invention without departing from the spirit and scope of the present invention as set forth in the claims below.

### INDUSTRIAL APPLICABILITY

The present invention is industrially applicable in the field of technology for synthesizing graphene on a catalytic metal by using Joule heating, which generates heat by applying current to a conductor during a roll-to-roll process in which a catalytic metal is continuously processed while being wound on a roll.

1. A method for manufacturing graphene using a Joule heating-based roll-to-roll graphene manufacturing apparatus having a first roller part and a second roller part for Joule heating a catalytic metal, the method comprising:
a current supply step of supplying current to the first roller part and the second roller part; and
a transfer step of transferring the catalytic metal,
wherein the transfer step comprises a synthesis area transfer step in which the catalytic metal passing through a temperature compensation area, which is an area between the first roller part and the second roller part, is transferred while maintaining a synthesis area extending downward due to its own weight, and the synthesis area is transferred in a state of maintaining a concave shape toward the temperature compensation area without a cross section distorted in a longitudinal direction.

2. The method of claim 1,
wherein the first roller part comprises a first upper roller and a first lower roller disposed on an opposite side of the first upper roller with the catalytic metal therebetween,
wherein the transfer step further comprises a synthesis area entry step in which a longitudinal direction cross section shape of the catalytic metal entering the temperature compensation area becomes a concave shape toward the temperature compensation area, and
wherein in the synthesis area entry step, one surface of the catalytic metal wraps around a part of the first upper roller and rotates in a first rotational direction, and then another surface of the catalytic metal wraps around a part of the first lower roller and rotates in a second rotational direction opposite to the first rotational direction.

3. The method of claim 2,
wherein the second roller part comprises a second upper roller and a second lower roller disposed on the opposite side of the second upper roller with the catalytic metal therebetween, and the transfer step further comprises a synthesis area release step in which the one surface of the catalytic metal is rotated in the second rotational direction while wrapping around a part of the second lower roller, and then the another surface of the catalytic metal is rotated in the first rotational direction while wrapping around a part of the second upper roller, thereby releasing the catalytic metal from the temperature compensation area.

4. The method of claim 3,
wherein in the synthesis area release step, the second upper roller and the second lower roller are arranged in an idle state with the catalytic metal therebetween.

5. The method of claim 3, wherein in the synthesis area entry step, the first upper roller and the first lower roller are pressed with a first pressure with the catalytic metal therebetween, and
wherein in the synthesis area release step, the second upper roller and the second lower roller are pressed with a second pressure less than the first pressure with the catalytic metal therebetween.

6. A method for manufacturing graphene using a Joule heating-based roll-to-roll graphene manufacturing apparatus having a first roller part and a second roller part for Joule heating a catalytic metal, the method comprising:
a current supply step of supplying current to the first roller part and the second roller part; and
a transfer step of transferring the catalytic metal,
wherein the transfer step comprises a synthesis area transfer step in which the catalytic metal passing through a temperature compensation area, which is an area between the first roller part and the second roller part, is transferred while maintaining a synthesis area extending downward due to its own weight, and the synthesis area is transferred in a state in which a cross section in a transverse direction maintains a concave shape toward the temperature compensation area.

7. A Joule heating-based roll-to-roll graphene manufacturing apparatus that supports a catalytic metal and is supplied with current to perform Joule heating so that graphene is synthesized with one surface of the catalytic metal, the Joule heating-based roll-to-roll graphene manufacturing apparatus comprising:
a first roller part supporting the catalytic metal; and
a second roller part disposed apart from the first roller part in a transfer direction of the catalytic metal,
wherein the catalytic metal has a synthesis area extending downward due to its own weight while passing through a temperature compensation area, which is an area between the first roller part and the second roller part, and wherein the synthesis area maintains a concave shape toward the temperature compensation area without a cross section distorted in a longitudinal direction.

8. The Joule heating-based roll-to-roll graphene manufacturing apparatus of claim 7, wherein the first roller part comprises:
a first upper roller that contacts and supports another surface of the catalytic metal and is configured to rotate the catalytic metal in a first rotational direction; and
a first lower roller that is disposed on an opposite side of the first upper roller with the catalytic metal therebetween, contacts and supports the one surface of the catalytic metal, and is configured to rotate the catalytic metal that has passed through the first upper roller in a second rotational direction opposite to the first rotational direction and enter the temperature compensation area.

9. The Joule heating-based roll-to-roll graphene manufacturing apparatus of claim 8, wherein the second roller part comprises:
a second lower roller that contacts and supports the one surface of the catalytic metal and is configured to rotate the catalytic metal in the second rotational direction; and
a second upper roller that is disposed on an opposite side of the second lower roller with the catalytic metal therebetween, contacts and supports the another surface of the catalytic metal, and is configured to rotate the catalytic metal that has passed through the second lower roller in the first rotational direction and release from the temperature compensation area.

10. The Joule heating-based roll-to-roll graphene manufacturing apparatus of claim 9, wherein the first roller part further comprises a first gap adjustment part that adjusts a first gap between the first upper roller and the first lower roller, and the second roller part further comprises a second gap adjustment part that adjusts a second gap between the second upper roller and the second lower roller.

11. The Joule heating-based roll-to-roll graphene manufacturing apparatus of claim 10,
wherein the first gap adjustment part comprises a first elastic member configured to support elastically at least one of the first upper roller and the first lower roller and configured to pass the catalytic metal between the first upper roller and press the first lower roller with a first pressure, and
wherein the second gap adjustment part comprises a second elastic member configured to support elastically at least one of the second upper roller and the second lower roller and configured to pass the catalytic metal between the second upper roller and press the second lower roller with a second pressure less than the first pressure.

12. The Joule heating-based roll-to-roll graphene manufacturing apparatus of claim 7, further comprising:
a chamber having an internal space of a vacuum atmosphere;
a supply part configured to unwind the catalytic metal wound around a supply roller to be supplied to the first roller part; and
a recovery part configured to recover the catalytic metal synthesized with graphene released from the second roller part while being wound around a recovery roller,
wherein the supply roller, the first roller part, the second roller part, and the recovery roller are arranged in the internal space.

13. The Joule heating-based roll-to-roll graphene manufacturing apparatus of claim 12, wherein the supply roller, the first roller part, the second roller part, and the recovery roller comprise a material that suppresses outgassing in the vacuum atmosphere.

14. The Joule heating-based roll-to-roll graphene manufacturing apparatus of claim 12, wherein each of the supply roller, the first roller part, the second roller part, and the recovery roller has a roller width corresponding to a width of the catalytic metal, and
wherein the roller width gradually increases in a direction of the supply roller, the first roller part, the second roller part, and the recovery roller.

15. A Joule heating-based roll-to-roll graphene manufacturing apparatus that supports a catalytic metal and is supplied with current to perform Joule heating so that graphene is synthesized with one surface of the catalytic metal, the Joule heating-based roll-to-roll graphene manufacturing apparatus comprising:
a first roller part supporting the catalytic metal; and
a second roller part disposed apart from the first roller part in a transfer direction of the catalytic metal,
wherein the catalytic metal has a synthesis area extending downward due to its own weight while passing through a temperature compensation area, which is an area between the first roller part and the second roller part, and a cross section in a transverse direction of the synthesis area maintains a concave shape toward the temperature compensation area.
